(19) United States
(12) Patent Application Publication
(10) Pub. No.: US 2026/0331415 A1
(43) Pub. Date: Oct. 22, 2026

(54) Ion Milling Device and Method for Processing Specimen

(71) Applicant: Hitachi High-Tech Corporation, Minato-ku, Tokyo (JP)

(72) Inventors: Kento HORINOUCHI, Tokyo (JP); Shota AIDA, Tokyo (JP)

(21) Appl. No.: 19/109,678

(22) PCT Filed: Sep. 8, 2022
(86) PCT No.: PCT/JP2022/033810

§ 371 Date: Mar. 7, 2025

(51) Int. Cl. H01J 37/20; H01J 37/305

(52) U.S. Cl. CPC H01J 37/20; H01J 37/3053; H01J 2237/026; H01J 2237/24585

(57) ABSTRACT

An ion milling device includes: a specimen stage (103) on which a specimen is placed; a specimen platform (102) and a shielding plate fixing portion (106) supported by the specimen stage; a shielding plate (105) fixed to the shielding plate fixing portion; an ion source (101) that irradiates the specimen with a non-focused ion beam; and a temperature adjustment unit (108) that is connected to the shielding plate fixing portion by a heat transfer cable (107) and configured to adjust a temperature of the shielding plate fixing portion. The specimen is sandwiched and held between the shielding plate and the specimen platform, and a protrusion amount of the specimen from the shielding plate is adjusted by a set temperature of the shielding plate fixing portion set in the temperature adjustment unit.

### TECHNICAL FIELD

The present invention relates to an ion milling device and a method for processing a specimen.

### BACKGROUND ART

An ion milling device is a device that can irradiate a specimen (for example, a metal, a semiconductor, glass, or ceramics), which is an object to be observed with an electron microscope, with a non-focused ion beam, remove atoms on a surface of the specimen by a sputtering phenomenon, polish the surface of the specimen with no stress, and expose an internal structure of the specimen. By the ion beam irradiation, the polished surface of the specimen and the internal structure of the specimen become observation surfaces of a scanning electron microscope or a transmission electron microscope.

Patent Literature 1 relates to a processing device that scrapes a portion protruding from a mask with an ion beam, and discloses a processing device in which a cooling mechanism is connected to a mask to be brought into contact with a specimen or that is provided with a cooling mechanism on a specimen platform, in order to reduce a thermal damage when the specimen is made of a material such as a polymeric material that has a low melting point and is susceptible to damage to the specimen structure such as deformation or contraction due to heat generated by energy of the ion beam.

### CITATION LIST

### Patent Literature

PTL 1: JP2010-257856A

### SUMMARY OF INVENTION

### Technical Problem

Among specimens to be processed by the ion milling device, there is a specimen that is affected by the thermal damage due to a temperature rise caused by ion beam irradiation, such as paper or a polymeric material. Examples of the thermal damage include melting and deformation of the specimen due to the ion beam irradiation.

As a method for reducing the thermal damage to the specimen, there is a method for reducing a protrusion amount of the specimen irradiated with the ion beam from a mask (shielding plate). During specimen processing, a non-focused ion beam is emitted from an ion source toward a specimen. By reducing the protrusion amount from the shielding plate, it is possible to prevent the specimen from being irradiated with an ion beam having a low-energy density, which contributes little to the specimen processing, and to prevent heating of the specimen. However, in this method, when an observation surface is present in a deep portion of the specimen, it is necessary to repeatedly adjust a boundary position between the specimen and the shielding plate and process the specimen.

The inventors have conducted a study to achieve a simple mechanism for adjusting the boundary position between the specimen and the shielding plate in the ion milling device, and have arrived at the invention. Patent Literature 1 discloses cooling of a mask or a specimen platform, but its purpose is to cool the specimen, and the invention does not disclose or suggest adjusting the boundary position between the specimen and the shielding plate using heat.

### Solution to Problem

An ion milling device according to an embodiment of the invention includes: a specimen stage on which a specimen is placed; a specimen platform and a shielding plate fixing portion that are supported by the specimen stage; a shielding plate fixed to the shielding plate fixing portion; an ion source that irradiates the specimen with a non-focused ion beam; and a temperature adjustment unit that is connected to the shielding plate fixing portion by a heat transfer cable and configured to adjust a temperature of the shielding plate fixing portion. The specimen is sandwiched and held between the shielding plate and the specimen platform, and a protrusion amount of the specimen from the shielding plate is adjusted by a set temperature of the shielding plate fixing portion set in the temperature adjustment unit.

### Advantageous Effects of Invention

Provided is an ion milling device capable of controlling a minute protrusion amount of a specimen with respect to a shielding plate with a simple mechanism. Other technical problems and novel features will become apparent from description of the present description and the accompanying drawings.

### BRIEF DESCRIPTION OF DRAWINGS

FIG. 1 is a configuration example (schematic diagram) of an ion milling device.

FIG. 2 is a schematic diagram showing an ion source and a power supply circuit for applying a control voltage to the ion source.

FIG. 3 is a schematic diagram showing a protrusion amount of a specimen with respect to a shielding plate for each temperature of a shielding plate fixing portion.

FIG. 4 is a flowchart showing an operation of specimen processing according to Embodiment 1.

FIG. 5 is a flowchart showing an operation of specimen processing according to Embodiment 2.

FIG. 6 is another configuration example (schematic diagram) of an ion milling device.

### DESCRIPTION OF EMBODIMENTS

Hereinafter, embodiments of the invention will be described with reference to the drawings.

### Embodiment 1

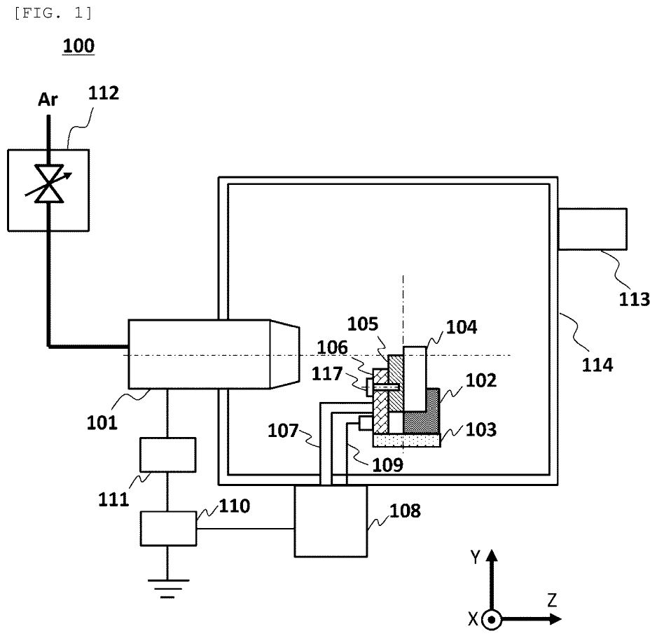

FIG. 1 is a schematic diagram showing, from a side, main parts of an ion milling device 100. In FIG. 1, a vertical direction is indicated as a Y direction. The ion milling device 100 includes, as its main components, an ion source 101, a specimen platform 102, a specimen stage 103, a specimen 104, a shielding plate 105, a shielding plate fixing portion 106, a heat transfer cable 107, a temperature adjustment unit 108, a first thermocouple 109, a control unit 110, a high-voltage power supply 111, a supply gas control unit 112, an exhaust mechanism 113, and a specimen chamber 114.

The ion milling device 100 is used as a pretreatment device for observing a surface or a cross section of a specimen by a scanning electron microscope or a transmission electron microscope, and an ion source for such a pretreatment device often employs a Penning system, which is effective in miniaturizing a structure. In the embodiment, the ion source 101 also adopts a Penning system, and a non-focused ion beam is emitted from the ion source 101 toward the specimen 104. The control unit 110 adjusts a a voltage applied to an electrode inside the ion source 101 from the high-voltage power supply 111 and a flow rate of an argon gas supplied from the supply gas control unit 112 to control an output of the ion beam.

The specimen 104 is placed on the specimen stage 103. The shielding plate 105 is fixed to the shielding plate fixing portion 106 by a shielding plate fixing screw 117, and the shielding plate fixing portion 106 is supported by the specimen stage 103. The specimen 104 is sandwiched between the specimen platform 102 supported by the specimen stage 103 and the shielding plate 105, and protrudes from the shielding plate 105 by a predetermined protrusion amount. The specimen stage 103 may be provided with a driving mechanism that freely drives the specimen 104 in five directions (an X-axis direction, a Y-axis direction, a Z-axis direction, a rotation direction about a Y axis, and a rotation direction about an X axis) or a part thereof.

In the embodiment, in order to adjust the protrusion amount of the specimen 104 from the shielding plate 105, thermal contraction of the shielding plate fixing portion 106 is used. Therefore, the shielding plate fixing portion 106 is desirably made of a material having a linear expansion coefficient as large as possible. For example, the shielding plate fixing portion 106 is made of phosphor bronze, brass, or the like. The shielding plate fixing portion 106 is connected to the temperature adjustment unit 108 via the heat transfer cable 107, and the temperature adjustment unit 108 adjusts the shielding plate fixing portion 106 to a temperature set by the control unit 110. A temperature adjustment method of the temperature adjustment unit 108 may employ various temperature adjustment methods and is not limited to a specific temperature adjustment method. When the ion beam is emitted, the specimen 104 and the shielding plate 105 are heated, and the temperature of the shielding plate fixing portion 106 rises due to heat transfer. Therefore, the temperature adjustment unit has at least a cooling function. For example, the shielding plate fixing portion 106 can be cooled using liquid nitrogen or dry ice. Meanwhile, since a degree of freedom of control increases as a controllable temperature is in a wider range, the temperature adjustment unit 108 may have both a cooling function and a heating function. For example, the above-described cooling and heating by a heater may be combined, or a Peltier element may be used.

The heat transfer cable 107 is made of a material having high heat conductivity such as copper. Since the specimen chamber 114 is maintained at a high vacuum (<1.0×10⁻³ Pa) by the exhaust mechanism 113 during milling processing, it is not necessary to consider heat dissipation from the heat transfer cable 107. The same applies to the shielding plate fixing portion 106. Temperature control of the shielding plate fixing portion 106 is performed by the first thermocouple 109, and when the temperature measured by the first thermocouple 109 greatly deviates from a set temperature, the temperature is adjusted by the temperature adjustment unit 108. The thermocouple is an example of a thermometer, and may not be a thermocouple as long as the temperature of the shielding plate fixing portion 106 can be measured.

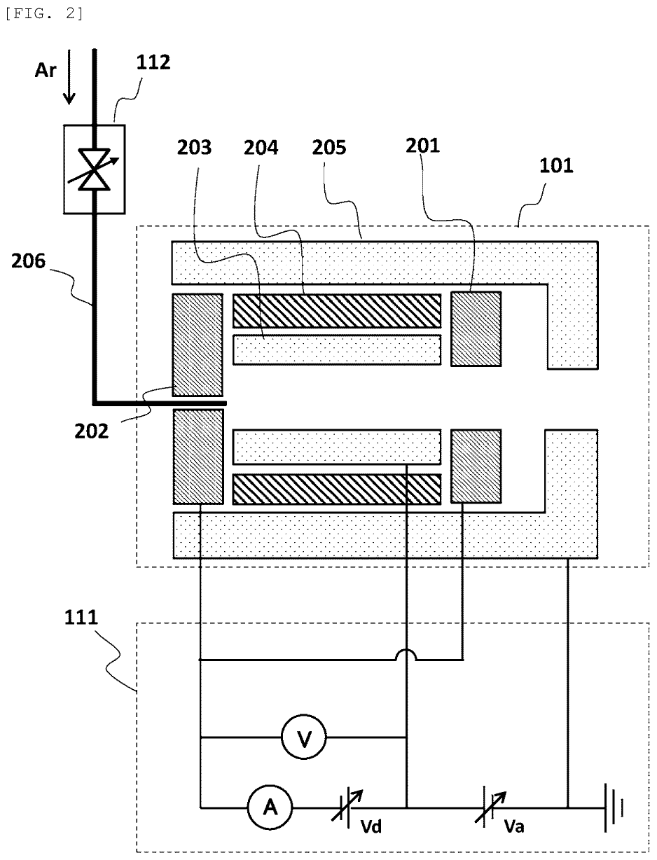

FIG. 2 is a schematic diagram showing the ion source 101 adopting the Penning system and a power supply circuit for applying a control voltage to electrode components of the ion source 101. The power supply circuit is a part of the high-voltage power supply 111.

The ion source 101 includes a first cathode 201, a second cathode 202, an anode 203, a permanent magnet 204, an acceleration electrode 205, and gas piping 206. In order to generate an ion beam, an argon gas is injected into the ion source 101 through the gas piping 206. In the ion source 101, the first cathode 201 and the second cathode 202 having the same potential are disposed facing each other, and the anode 203 is disposed between the first cathode 201 and the second cathode 202. When a discharge voltage Vd from the high-voltage power supply 111 is applied between the cathodes 201 and 202 and the anode 203, electrons are generated. The electrons are retained by the permanent magnet 204 disposed in the ion source 101 and collide with the argon gas injected from the gas piping 206 to generate argon ions. An acceleration voltage Va from the high-voltage power supply 111 is applied between the anode 203 and the acceleration electrode 205, and the generated argon ions are attracted to the acceleration electrode 205 and emitted as an ion beam.

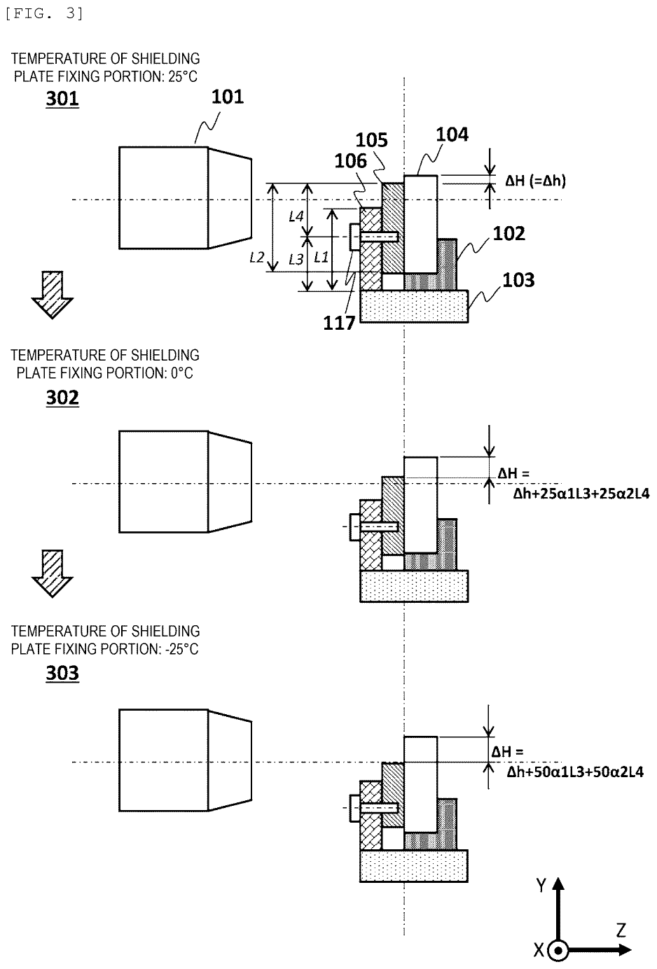

In FIG. 3, schematic diagrams showing a protrusion amount ←H of the specimen 104 with respect to the shielding plate 105 for each temperature of the shielding plate fixing portion 106 are shown as states 301 to 303. The temperatures of the shielding plate fixing portion 106 in the states 301 to 303 are 25 °C, 0 °C, and −25 °C, respectively. Since the shielding plate 105 and the specimen 104 are merely in close contact with each other, a boundary (an edge) between the shielding plate 105 and the specimen 104 is moved by expansion and contraction of the shielding plate fixing portion 106 and the shielding plate 105 by cooling or heating the shielding plate fixing portion 106. Accordingly, a distance (a protrusion amount) ΔH from the edge to an end surface of the specimen 104 changes.

When the temperature of the shielding plate fixing portion 106 is 25 °C (the state 301), the protrusion amount ΔH of the specimen 104 with respect to the shielding plate 105 is Δh, a total length of the shielding plate fixing portion 106 is L1, a distance from a bottom surface of the shielding plate fixing portion 106 to a shielding plate fixing screw 117 is L3, and a linear expansion coefficient of the shielding plate fixing portion 106 is α1. A total length of the shielding plate 105 is L2, a distance from the shielding plate fixing screw 117 to the end surface of the shielding plate 105 is L4, and a linear expansion coefficient of the shielding plate 105 is α2.

When the temperature of the shielding plate fixing portion 106 is 0 °C (the state 302), a temperature difference from the state 301 is 25 °C, and thus the shielding plate fixing portion 106 and the shielding plate 105 contract by 25×α1×L1 and 25×α2×L2, respectively. The position of the shielding plate 105 is lowered by the thermal contraction of the shielding plate fixing portion 106, and the shielding plate 105 itself is also contracted by the thermal contraction, and as a result, the protrusion amount ΔH in the state 302 becomes (Formula 1).

ΔH=Δh+25∴α1×L3+25×α2×L4 (Formula 1)

In the right side of (Formula 1), the first term represents the protrusion amount in the state 301, the second term represents a change amount of the position of the shielding plate fixing screw 117 due to the thermal contraction of the shielding plate fixing portion 106, and the third term represents a contraction amount of the shielding plate 105 with the shielding plate fixing screw 117 as a fulcrum due to the thermal contraction of the shielding plate 105. As described above, the protrusion amount ΔH also depends on a support structure of the shielding plate fixing portion 106 and the shielding plate 105. The support structure of the shielding plate fixing portion 106 and the shielding plate 105 shown in the schematic diagram of FIG. 3 is an example, and the present embodiment is not limited to a specific support structure.

Similarly, when the temperature of the shielding plate fixing portion 106 is −25 °C (the state 303), the temperature difference from the state 301 is 50 °C, and thus the shielding plate fixing portion 106 and the shielding plate 105 contract by 50×α1×L1 and 50×α2×L2, respectively. The protrusion amount ΔH in the state 303 can be represented by Formula 2.

ΔH=Δh+50×α1×L3+50×α2×L4 (Formula 2)

As described above, the protrusion amount AH of the specimen 104 from the shielding plate 105 changes according to a linear function having the temperature difference as a variable.

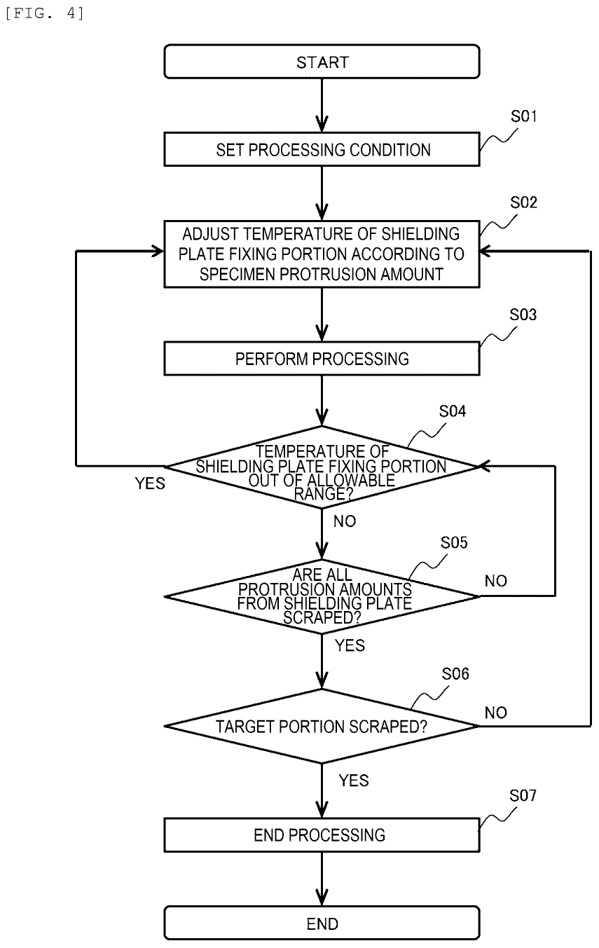

A flowchart shown in FIG. 4 shows a series of operations from the start to the end of specimen processing in the ion milling device according to Embodiment 1. A series of operations in this flowchart is executed by the control unit 110. Details of each operation will be described below.
S01: A specimen processing condition of the ion milling device 100 (an acceleration voltage of the ion source 101, a discharge voltage, a supply amount of an argon gas, and the like) is set. The specimen processing condition includes the specimen protrusion amount Δh of the specimen 104 with respect to the shielding plate 105 at the start of the milling processing, and the specimen protrusion amount Δh to be set is desirably set to a value as small as possible.
S02: The control unit 110 sets a temperature (referred to as a set temperature) corresponding to the specimen protrusion amount Δh set in step S01, and adjusts the temperature of the shielding plate fixing portion 106 to the set temperature by the temperature adjustment unit 108. When the processing is performed continuously from step S01, the specimen 104 is sandwiched between the shielding plate 105 and the specimen platform 102 such that the protrusion amount from the shielding plate is Δh at a room temperature. Accordingly, it is unnecessary to adjust the temperature of the shielding plate fixing portion 106 when starting the milling processing.
S03: The specimen 104 is irradiated with an ion beam from the ion source 101 to process the specimen 104 (milling processing).
S04: The temperature of the shielding plate fixing portion 106 is monitored by the first thermocouple 109 during the milling processing. When the temperature of the shielding plate fixing portion 106 is out of an allowable range of the set temperature due to the heating associated with the milling processing for a long time, the processing is temporarily stopped and returns to S02, and the shielding plate fixing portion 106 is cooled. As soon as the temperature of the shielding plate fixing portion 106 returns to the set temperature set in step S02, the processing is restarted (S03).
S05: It is checked whether the entire portion of the specimen 104 protruding from the shielding plate 105 is scraped. When the portion is not scraped, the processing is continued (S03). A checking method is not limited. As a simplest method, it may be determined that a protruding portion is scraped when a predetermined processing time elapses. A transparent window may be provided in a specimen chamber, and the specimen may be directly checked through the window by a monitoring component such as an optical microscope or an electron microscope. Alternatively, a processing amount may be estimated from an amount of sputtered particles generated during the specimen processing.
S06: It is checked whether a target portion of the specimen 104 is scraped. The target portion is, for example, a cross section to be an observation surface when the main processing is preprocessing for observing a cross section of the specimen 104 by a scanning electron microscope or a transmission electron microscope. When the target portion is not scraped, the processing returns to step S02 to control the temperature of the shielding plate fixing portion 106 so that the protrusion amount of the specimen from the shielding plate is Δh. Specifically, the set temperature is reset to a temperature that is lower by ΔT than the set temperature during the previous temperature control, and the temperature adjustment unit 108 cools the shielding plate fixing portion 106 to the reset set temperature. For example, in the example of FIG. 3, ΔT=Δh/(α1L3+α2L4).
S07: If the target portion is scraped, the processing ends.

As described above, in Embodiment 1, by adjusting the temperature of the shielding plate fixing portion 106, a minute protrusion amount of the specimen from the shielding plate can be adjusted by a simple mechanism. Accordingly, by performing cross section milling processing with the protrusion amount kept as small as possible, it is possible to minimize a thermal load on the specimen 104 caused by the cross section milling processing. Accordingly, it is possible to reduce a thermal damage to the specimen 104 due to ion beam irradiation.

### Embodiment 2

As Embodiment 2, an ion milling device capable of reducing an influence of a temperature drift due to ion beam irradiation on the shielding plate 105 will be described. The hardware configuration of the ion milling device according to Embodiment 2 is the same as that of the ion milling device 100 shown in FIG. 1, and thus a redundant description will be omitted. In Embodiment 2, a temperature of the shielding plate fixing portion 106 before the start of processing, when no ion beam is irradiated, is stored as a reference temperature. £ When the temperature of the shielding plate fixing portion 106 deviates from the reference temperature due to ion beam irradiation after the start of processing, the temperature adjustment unit 108 adjusts the temperature of the shielding plate fixing portion 106 to the reference temperature. Accordingly, the influence of the temperature drift of the shielding plate 105 during the cross section milling processing can be reduced, and the processing can be performed in a state where the position of the boundary (the edge) between the shielding plate 105 and the specimen 104 is maintained at the position at the start of the processing.

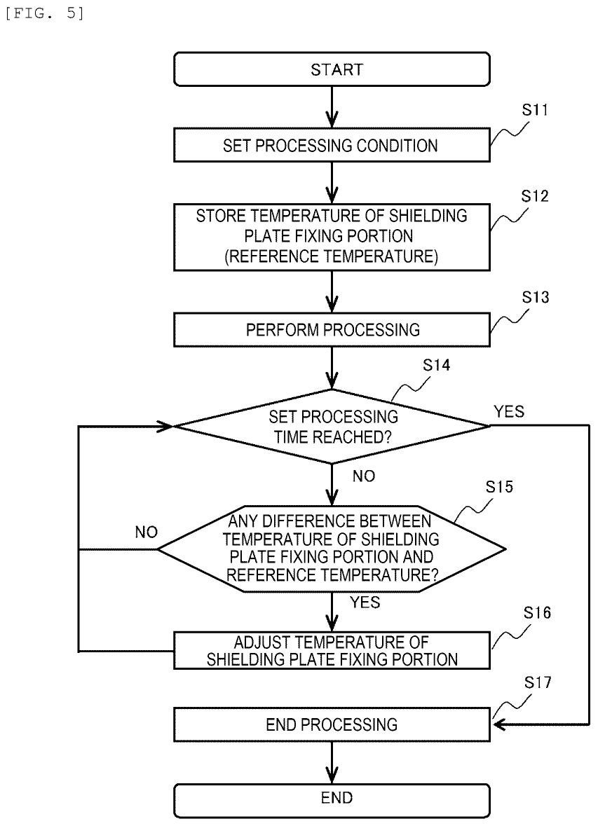

A flowchart shown in FIG. 5 shows a series of operations from the start to the end of specimen processing in the ion milling device according to Embodiment 2. A series of operations in this flowchart is executed by the control unit 110. Details of each operation will be described below.
S11: A specimen processing condition of the ion milling device 100 (an acceleration voltage of the ion source 101, a discharge voltage, a supply amount of an argon gas, and the like) is set. When the main processing is preprocessing for observing the cross section of the specimen 104 with a scanning electron microscope or a transmission electron microscope, the specimen 104 is sandwiched between the shielding plate 105 and the specimen platform 102 so that the cross section serving as the observation surface is located at the boundary (the edge) between the shielding plate 105 and the specimen 104. As the specimen processing condition, a specimen processing time required for milling a region of the specimen 104 protruding from the shielding plate 105 is set.
S12: A temperature of the shielding plate fixing portion 106 measured by the first thermocouple 109 is stored as a reference temperature.
S13: The specimen 104 is irradiated with an ion beam from the ion source 101 to process the specimen 104 (milling processing).
S14: A processing time is monitored during the milling processing.
S15: The temperature of the shielding plate fixing portion 106 is monitored by the first thermocouple 109 during the milling processing.
S16: When there is a difference between the temperature of the shielding plate fixing portion 106 and the reference temperature, the temperature adjustment unit 108 performs temperature adjustment such that the shielding plate fixing portion 106 reaches the reference temperature, and continues the processing.
S17: When the set specimen processing time is reached, the processing ends.

As described above, the ion milling device 100 includes the thermocouple 109 as the first thermometer that measures the temperature of the shielding plate fixing portion 106, and the control unit 110 in which the specimen processing time is set, and the control unit 110 stores the temperature of the shielding plate fixing portion 106 measured by the thermocouple 109 serving as the first thermometer as the reference temperature before the ion beam irradiation from the ion source 101, and maintains the temperature of the shielding plate fixing portion 106 measured by the thermocouple 109 serving as the first thermometer at the reference temperature by the temperature adjustment unit 108 during the ion beam irradiation from the ion source 101. Accordingly, it is possible to provide an ion milling device capable of controlling a minute protrusion amount of the specimen with respect to the shielding plate with a simple mechanism.

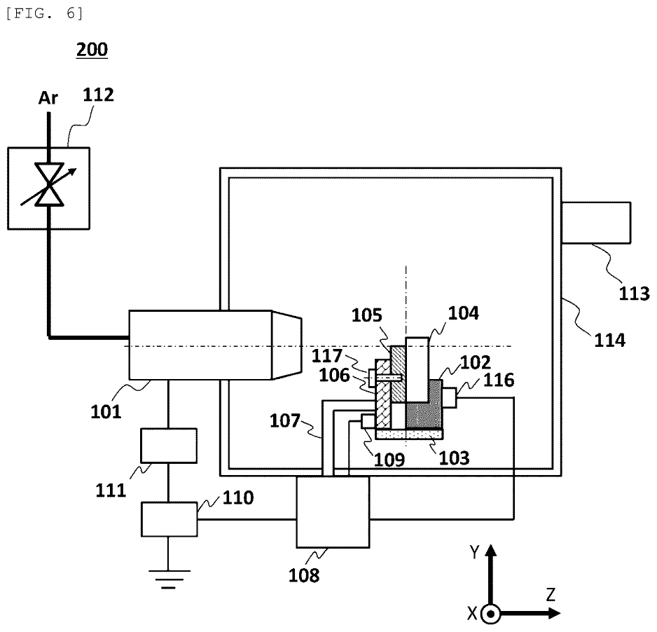

FIG. 6 shows a modification of the ion milling device. Components same as those of the ion milling device shown in FIG. 1 are denoted by the same reference numerals, and a redundant description will be omitted. A second thermocouple 116 for checking the temperature of the specimen 104 is added to an ion milling device 200. A thermometer other than the thermocouple may be used for the second thermocouple 116. With this configuration, since the adjustment of the protrusion amount can be calculated including a thermal contraction amount or a thermal expansion amount of the specimen 104 in addition to a thermal contraction amount of the shielding plate fixing portion 106 and the shielding plate 105, it is possible to more precisely adjust the protrusion amount of the specimen from the shielding plate. This configuration is effective when the material of the specimen 104 has a relatively large linear expansion coefficient.

Although the invention made by the present inventor has been specifically described based on embodiments, the invention is not limited to the embodiments described above, and various modifications can be made without departing from the gist of the invention. For example, although the embodiment in which the specimen protrusion amount is adjusted by adjusting the temperature of the shielding plate fixing portion 106 is described, the temperature of the shielding plate 105 may be directly adjusted.

The invention is not limited to the embodiments described above, and includes various modifications. For example, the above-described embodiments have been described in detail to facilitate understanding of the invention, and the invention is not necessarily limited to those including all the configurations described. A part of a configuration of a certain embodiment can be replaced with a configuration of another embodiment, and a configuration of another embodiment can be added to a configuration of a certain embodiment. A part of a configuration of each embodiment may be added to, deleted from, or replaced with another configuration.

### REFERENCE SIGNS LIST

100, 200: ion milling device
101: ion source
102: specimen platform
103: specimen stage
104: specimen
105: shielding plate
106: shielding plate fixing portion
107: heat transfer cable
108: temperature adjustment unit
109: first thermocouple
110: control unit
111: high-voltage power supply
112: supply gas control unit
113: exhaust mechanism
114: specimen chamber
116: second thermocouple
117: shielding plate fixing screw
201: first cathode
202: second cathode
203: anode
204: permanent magnet
205: acceleration electrode
206: gas piping

1. An ion milling device comprising:
a specimen stage on which a specimen is placed;
a specimen platform and a shielding plate fixing portion that are supported by the specimen stage;
a shielding plate fixed to the shielding plate fixing portion;
an ion source that irradiates the specimen with a non-focused ion beam; and
a temperature adjustment unit that is connected to the shielding plate fixing portion by a heat transfer cable and configured to adjust a temperature of the shielding plate fixing portion, wherein
the specimen is sandwiched and held between the shielding plate and the specimen platform, and
a protrusion amount of the specimen from the shielding plate is adjusted by a set temperature of the shielding plate fixing portion set in the temperature adjustment unit.

2. The ion milling device according to claim 1, wherein
the temperature adjustment unit cools the shielding plate fixing portion.

3. The ion milling device according to claim 1, wherein
the temperature adjustment unit cools or heats the shielding plate fixing portion.

4. The ion milling device according to claim 1, further comprising:
a control unit in which a specimen protrusion amount is set, wherein
the control unit irradiates the specimen with an ion beam from the ion source after the temperature adjustment unit adjusts the temperature of the shielding plate fixing portion to the set temperature, and
the set temperature is set as a temperature at which the protrusion amount of the specimen from the shielding plate becomes the specimen protrusion amount.

5. The ion milling device according to claim 4, wherein
the control unit stops irradiation with the ion beam from the ion source after a portion of the specimen protruding from the shielding plate is scraped, resets the set temperature at which the protrusion amount of the specimen from the shielding plate becomes the specimen protrusion amount again, and restarts the irradiation with the ion beam from the ion source after the temperature adjustment unit adjusts the temperature of the shielding plate fixing portion to the reset set temperature.

6. The ion milling device according to claim 4, further comprising:
a first thermometer configured to measure the temperature of the shielding plate fixing portion, wherein
when the temperature of the shielding plate fixing portion measured by the first thermometer is out of an allowable range of the set temperature, the control unit stops irradiation with the ion beam from the ion source and adjusts the temperature of the shielding plate fixing portion to the set temperature by the temperature adjustment unit.

7. The ion milling device according to claim 1, further comprising:
a first thermometer configured to measure a temperature of the shielding plate fixing portion; and
a control unit in which a specimen processing time is set, wherein
the control unit stores the temperature of the shielding plate fixing portion measured by the first thermometer as a reference temperature before ion beam irradiation from the ion source, and maintains the temperature of the shielding plate fixing portion measured by the first thermometer at the reference temperature by the temperature adjustment unit during the ion beam irradiation from the ion source.

8. The ion milling device according to claim 1, further comprising:
a second thermometer configured to measure a temperature of the specimen.

9. A method for processing a specimen using an ion milling device, the ion milling device including a specimen stage on which a specimen is placed, a specimen platform and a shielding plate fixing portion that are supported by the specimen stage, a shielding plate fixed to the shielding plate fixing portion, an ion source that irradiates the specimen with a non-focused ion beam, a temperature adjustment unit that is connected to the shielding plate fixing portion by a heat transfer cable and configured to adjust a temperature of the shielding plate fixing portion, and a control unit in which a specimen protrusion amount is set, the method comprising:
adjusting, by the temperature adjustment unit, the temperature of the shielding plate fixing portion to a set temperature; and
irradiating, by the ion source, the specimen sandwiched and held between the shielding plate and the specimen platform with an ion beam, wherein
the set temperature is set as a temperature at which a protrusion amount of the specimen from the shielding plate becomes the specimen protrusion amount.

10. The method for processing a specimen according to claim 9, further comprising:
stopping, by the ion source, irradiation with the ion beam after a portion H the specimen protruding from the shielding plate is scraped;
resetting, by the control unit, the set temperature at which the protrusion amount of the specimen from the shielding plate becomes the specimen protrusion amount again;
adjusting, by the temperature adjustment unit, the temperature of the shielding plate fixing portion to the reset set temperature; and
restarting, by the ion source, the irradiation with the ion beam.

11. The method for processing a specimen according to claim 9, executed by the ion milling device further including a thermometer configured to measure a temperature of the shielding plate fixing portion, the method further comprising:
stopping, by the ion source, irradiation with the ion beam when the temperature of the shielding plate fixing portion measured by the thermometer is out of an allowable range of the set temperature; and
adjusting, by the temperature adjustment unit, the temperature of the shielding plate fixing portion to the set temperature.

12. A method for processing a specimen using an ion milling device, the ion milling device including a specimen stage on which a specimen is placed, a specimen platform and a shielding plate fixing portion that are supported by the specimen stage, a shielding plate fixed to the shielding plate fixing portion, an ion source configured to irradiate the specimen with a non-focused ion beam, a temperature adjustment unit that is connected to the shielding plate fixing portion by a heat transfer cable and configured to adjust a temperature of the shielding plate fixing portion, a thermometer configured to measure the temperature of the shielding plate fixing portion, and a control unit in which a specimen processing time is set, the method comprising:
storing, by the control unit, the temperature of the shielding plate fixing portion measured by the thermometer as a reference temperature before ion beam irradiation from the ion source;
irradiating, by the ion source, the specimen sandwiched and held between the shielding plate and the specimen platform with an ion beam; and
maintaining, by the temperature adjustment unit, the temperature of the shielding plate fixing portion measured by the thermometer at the reference temperature during the ion beam irradiation from the ion source.
